(19) United States
(12) Patent Application Publication
(10) Pub. No.: US 2006/0001180 A1
(43) Pub. Date: Jan. 5, 2006

(54) In-line wire bonding on a package, and method of assembling same

(76) Inventors: Brian Taggart, Phoenix, AZ (US); Robert Nickerson, Chandler, AZ (US); Ronald L. Spreitzer, Phoenix, AZ (US)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(21) Appl. No.: 10/882,998

(22) Filed: Jun. 30, 2004

(51) Int. Cl. H01L 23/48; H01L 21/44

(52) U.S. Cl. 257/786; 257/784; 438/666; 438/612

(57) ABSTRACT

A wire-bonding substrate includes in-line wire bonds that are substantially of the same pitch on the die bond pads as on the substrate bond pads. A wire-bonding substrate also includes staggered bond pads on at least one of the die and the substrate. A substrate bond pad includes a first wire-bond pad and a first via that is disposed directly below the first wire-bond pad in the wire-bonding substrate. A package is also disclosed that includes a die that is coupled to the first wire-bonding pad. A computing system is also disclosed that includes the in-line wire-bonding configuration.

### BACKGROUND INFORMATION

1. Technical Field

Disclosed embodiments relate to a wire-bond technology for a substrate. More particularly, disclosed embodiments relate to bond fingers on the substrate that are aligned with their respective die pads on silicon.

2. Description of Related Art

A wire-bonding package usually requires significant routing of traces within a printed circuit board (PCB). The advent of wireless technologies has led to a push to miniaturize packaged integrated circuits such that conventional wire bonding has become a hindrance with the push to miniaturize. Additionally, various traces on the surface of the PCB, that are routed to locations remote from the wire bond, can result in significant cross-talk that diminishes the performance of the packaged integrated circuit.

### BRIEF DESCRIPTION OF THE DRAWINGS

In order to understand the manner in which embodiments are obtained, a more particular description of various embodiments briefly described above will be rendered by reference to the appended drawings. Understanding that these drawings depict only typical embodiments that are not necessarily drawn to scale and are not therefore to be considered to be limiting of its scope, some embodiments will be described and explained with additional specificity and detail through the use of the accompanying drawings in which:

FIG. 1 is a side cross-section of a mounting substrate according to an embodiment;

FIG. 2 is a side cross-section of the mounting substrate in FIG. 1 after assembly with a die to form a package, according to an embodiment;

FIG. 3 is a top plan of a package similar to the package depicted in FIG. 2 according to an embodiment;

FIG. 4 is a top plan of a package according to an embodiment;

FIG. 5 is a side cut-away of the package depicted in FIG. 4 according to an embodiment;

FIG. 6 is a side cross-section a of package according to an embodiment;

FIG. 7 is a top plan of a package similar to the package depicted in FIG. 6 according to an embodiment;

FIG. 8 is a side cross-section of a package according to an embodiment;

FIG. 9 is a top plan of a package according to an embodiment;

FIG. 10 is a top plan of a package according to an embodiment;

FIG. 11 is a side cross-section of a package according to an embodiment;

FIG. 12 is a process flow diagram according to various embodiments; and

FIG. 13 is a depiction of a computing system according to an embodiment.

### DETAILED DESCRIPTION

The following description includes terms, such as upper, lower, first, second, etc. that are used for descriptive purposes only and are not to be construed as limiting. The embodiments of a device or article described herein can be manufactured, used, or shipped in a number of positions and orientations. The terms “die” and “processor” generally refer to the physical object that is the basic workpiece that is transformed by various process operations into the desired integrated circuit device. A board is typically a resin-impregnated fiberglass structure that acts as a mounting substrate for the die. A die is usually singulated from a wafer, and wafers may be made of semiconducting, non-semiconducting, or combinations of semiconducting and non-semiconducting materials.

Reference will now be made to the drawings wherein like structures will usually be provided with like reference designations. In order to show the structure and process embodiments most clearly, the drawings included herein are diagrammatic representations of embodiments. Thus, the actual appearance of the fabricated structures, for example in a photomicrograph, may appear different while still incorporating the essential structures of embodiments. Moreover, the drawings show only the structures necessary to understand the embodiments. Additional structures known in the art have not been included to maintain the clarity of the drawings.

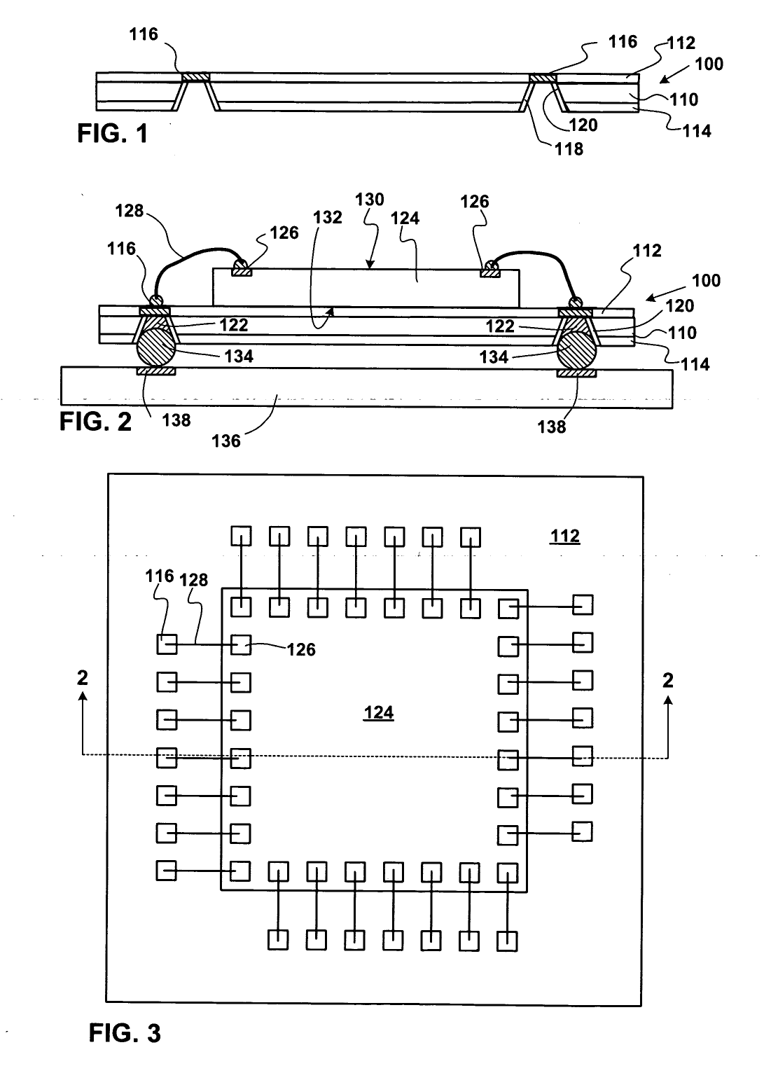

FIG. 1 is a side cross-section of a mounting substrate 100 according to an embodiment. The mounting substrate 100 includes a substrate core 110, an upper protective layer 112, and a lower protective layer 114. A wire-bond pad 116 is depicted on the upper protective layer 112. In an embodiment, the wire-bond pad 116 is depicted as a structure that is flush with the upper protective layer 112. In an embodiment, a via liner 118 is a metallic or otherwise electrically conductive material that provides an electrical path through the mounting substrate 100, within a via 120.

Formation of the via 120 can be accomplished by various process flows. In an embodiment, the wire-bond pad 116 is first formed, and the via 120 is formed by laser drilling through the lower protective layer 114, the substrate core 110, and finally through the upper protective layer 112. In an embodiment, the laser drilling is operated to stop on the wire-bond pad 116. In an embodiment, laser drilling is done by drilling at a site that is later occupied by wire-bond pad 116. In this embodiment, the laser drilling is done first, and the placement of the wire-bond pad 116 is done subsequently.

FIG. 2 is a side cross-section of the mounting substrate 100 in FIG. 1 after assembly with a die to form a package, according to an embodiment. In an embodiment, the via 120 is filled with an interconnect 122. In an embodiment, the via 120 is not filled, as depicted in FIG. 1, and the electrical path relies substantially upon the via liner 118.

A die 124 is depicted mounted upon the mounting substrate 100 at the upper protective layer 112. The die 124 includes an active surface 130 and a backside surface 132. Electrical coupling of the die 124 to the via 120 is done between a die bond pad 126, a bond wire 128, and the wire-bond pad 116. The die bond pad 126 is disposed upon the active surface 130 of the die 124. Although not depicted, the die 124 is adhered to the mounting substrate 100 by a material such as an organic, thermal adhesive or the like. The adhesive is disposed between the backside surface 132 of the die 124 and the upper protective layer 112.

FIG. 2 also depicts electrical coupling of the die 124 to a larger substrate 136. The die 124 is coupled to a bump 134, which in an embodiment, is at least partially disposed in the via 120. The bump 134 can be any electrical connection such as a solder ball. According to an embodiment, the vertical profile of the entire package is lower due to the bump 134 being at least partially embedded in the mounting substrate 100. In an embodiment, the larger substrate 136 is a motherboard, a mezzanine board, an expansion card, or others. In an embodiment, the larger substrate 136 is a penultimate casing for a wireless handheld such as a wireless telephone.

In an embodiment, a process of wirebonding includes reverse wire bonding. The process includes first attaching the bond wire 128 at the wire-bond pad 116, followed by second attaching the bond wire 128 at the die bond pad 126. In an embodiment, a process of wirebonding includes forward wire bonding. The process includes first attaching the bond wire 128 at the die bond pad 126, followed by second attaching the bond wire 128 at the wire-bond pad 116.

FIG. 3 is a top plan of a package similar to the package depicted in FIG. 2 according to an embodiment. The view of FIG. 2 can be taken along the line 2—2. The die 124 is depicted mounted upon the upper protective layer 112. The die bond pad 126 is coupled to the wire-bond pad 116 through the bond wire 128. In this embodiment, the plurality of wire-bond pads 116 is depicted as substantially the same size and pitch as the plurality of die bond pads 126. By “substantially the same size and pitch” it is understood that where the wire-bond pads 116 are spaced from each other on e.g., 200 micrometer (μm) centers, and the die bond pads 126 are similarly spaced on 200 μm centers. In an embodiment, the pitch is in a range from about 10 μm to about 200 μm. In an embodiment, the pitch is about 135 μm.

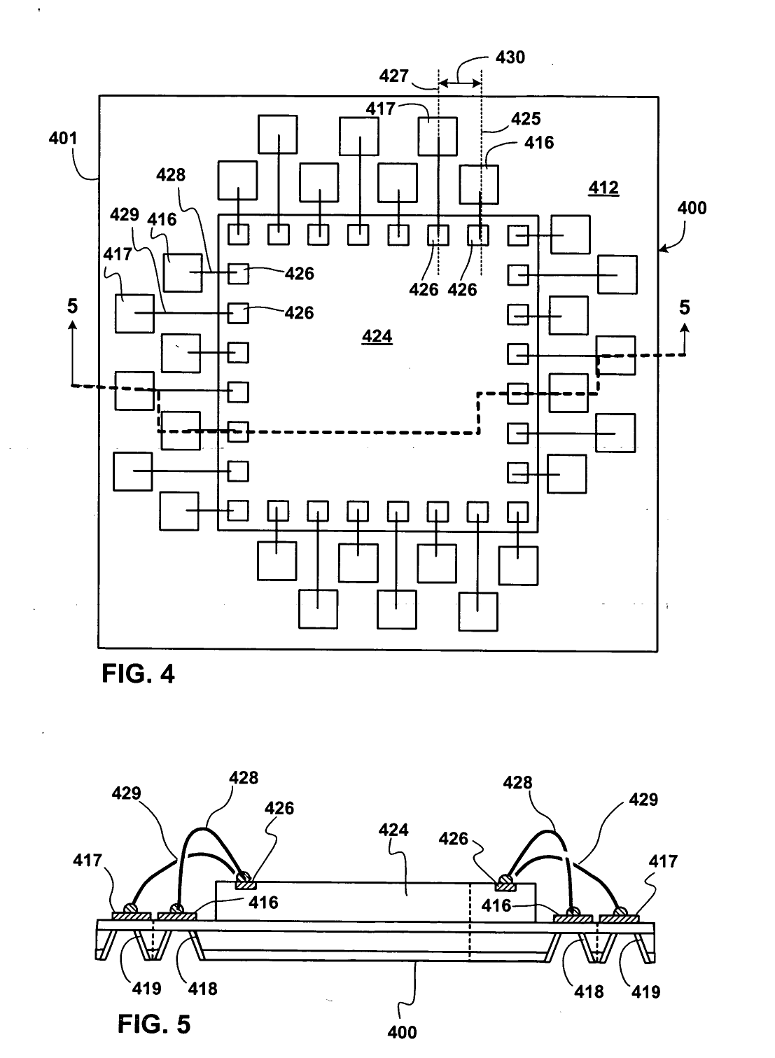

FIG. 4 is a top plan of a package according to an embodiment. A die 424 is depicted mounted upon an upper protective layer 412 of a mounting substrate 400. A plurality of first wire-bond pads 416 is arrayed substantially parallel to an edge 401 of the mounting substrate 400. A plurality of second wire-bond pads 417 is also arrayed substantially parallel to the edge 401 of the mounting substrate 400. The plurality of second wire-bond pads 417, however, is arrayed at a distance from the edge 401 that is less than the plurality of first wire-bond pads 416. In other words, a given first wire-bond pad 416 and a given second wire-bond pad 417 are arrayed in a staggered configuration with respect to the edge 401 of the mounting substrate 400. In an embodiment, the staggered configuration allows a larger bump (not pictured) to couple the die 424 to the outside world, without shorting into a contiguous bump. In an embodiment, the plurality of first wire-bond pads 416 is arrayed with a first pitch in relation to the plurality of second wire-bond pads 417.

The staggered configuration includes substantially the same pitch as the plurality of die bond pads 426. The substantially same pitch is defined by the spacing 430, which is the orthogonal distance, between a first symmetry line 425 and a second symmetry line 427. In other words, the overall pitch of the wire-bond pads 416, 417 is staggered. The staggered wire bond pads 416 and 417 include a second pitch that is quantified by a first substrate bond pad 416 disposed along the first symmetry line 425 and the second substrate bond pad 419 is disposed along the second symmetry line 427. As set forth herein, the first symmetry line 425 and the second symmetry line 427 are spaced apart by a distance substantially equivalent to the first pitch of the die bond pads 426.

FIG. 5 is a side cut-away of the package depicted in FIG. 4 according to an embodiment. The substrate 400 includes a first via 418 and a second via 419. As taken along the line 5—5 in FIG. 4, the substrate 400 is cut away to reveal the staggered configuration of the first via 418 and the second via 419. In an embodiment, the first via 418 is disposed directly below the first wire-bond pad 416. Similarly in an embodiment, the second via 419 is disposed directly below the second wire-bond pad 417. In an embodiment (not pictured), only one of the first via 418 and the second via 419 is disposed directly below its respective wire-bond pads. In an embodiment (not pictured), neither of the first via 418 nor the second via 419 is disposed directly below its respective wire-bond pad.

In an embodiment, electronic tuning of the package is done by making the first bond wire 428 the same length, or the like, as the second bond wire 429. Although the first wire-bond pad 416 is closer to its respective die bond pad 426 than the second wire-bond pad 417 is to its respective die bond pad (not pictured), the lengths of the respective bond wires 428 and 429 are tuned to achieve a similar signal delay during operation of the die 424.

In an embodiment, a process of wirebonding includes reverse wire bonding. The process includes first attaching the first bond wire 428 at the first wire-bond pad 416, followed by second attaching the first bond wire 428 at a first die bond pad 426. Similarly, the process includes first attaching the second bond wire 429 at the second wire-bond pad 417, followed by second attaching the second bond wire 429 at a second die bond pad (not pictured). In an embodiment, a process of wirebonding includes forward wire bonding. The process includes first attaching the first bond wire 428 at the first die bond pad 426, followed by second attaching the first bond wire 428 at the first wire-bond pad 416. Similarly, the process includes first attaching the second bond wire 429 at a second die bond pad (not pictured), followed by second attaching the second bond wire 429 at the second wire-bond pad 417.

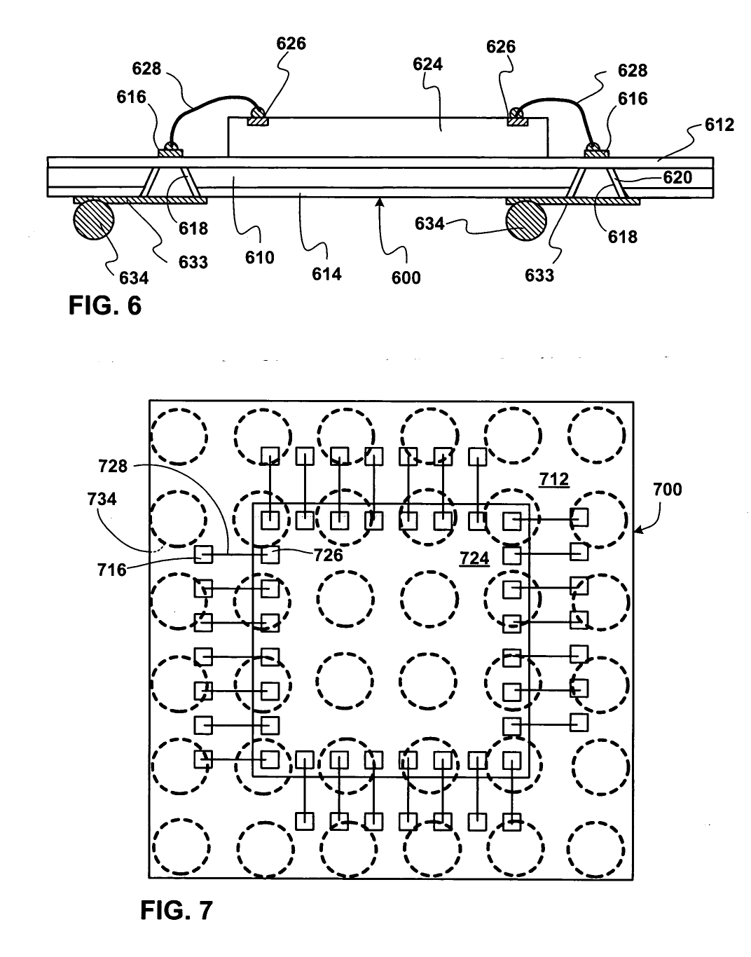

FIG. 6 is a side cross-section of a package according to an embodiment. In an embodiment, it is not always the case that a given bump can be or is desired to be lodged in the via with which it communicates. FIG. 6 depicts a mounting substrate 600 that includes a substrate core 610, an upper protective layer 612, and a lower protective layer 614. A first via 618 is depicted penetrating the substrate core 610, the upper protective layer 612, and the lower protective layer 614. A wire-bond pad 616, also referred to as a bond finger 616 is depicted directly above the first via 618. In an embodiment, a second via (not pictured) such as the second via 419 in FIG. 5, provides electrical communication for a staggered wire-bond pad array such as is depicted in FIG. 4.

The wire-bond pad 616 is depicted as a raised structure above the upper protective layer 612. In an embodiment, the wire-bond pad 616 is at least flush with the upper protective layer 612. In an embodiment, a via liner 620 is a metallic or otherwise electrically conductive material that provides an electrical path through the mounting substrate 600.

FIG. 6 also depicts a die 624 disposed upon the upper protective layer 612. Additionally, a bump 634 is disposed below the mounting substrate 600 that is not directly below the first via 618. The bump 634 is coupled to the first via 618 by a first trace 633. Consequently, the die 624 communicates to the bump 634 commencing with a die bond pad 626, the bond wire 628, the first wire-bond pad 616, and the trace 633.

In an embodiment, the first via 618 is filled with an interconnect (not pictured) such as the interconnect 122 depicted in FIG. 2. In an embodiment, the first via 618 is not filled, as depicted in FIG. 6, and the electrical path relies substantially upon the via liner 620. Electrical coupling of the die 624 to the first via 618 is done between the die bond pad 626, the bond wire 628, and the bond finger 616.

In an embodiment, a process of wirebonding includes reverse wire bonding. The process includes first attaching the first bond wire 628 at the first wire-bond pad 616, followed by second attaching the first bond wire 628 at a first die bond pad 626. Where a second bond wire is present for a staggered wire-bond pad with respect to the first wire-bond pad 616, the process includes first attaching the second bond wire at the second wire-bond pad, followed by second attaching the second bond wire at a second die bond pad. In an embodiment, a process of wirebonding includes forward wire bonding. The process includes first attaching the first bond wire 628 at the first die bond pad 626, followed by second attaching the first bond wire 628 at the first wire-bond pad 616. Where a second bond wire is present for a staggered wire-bond pad with respect to the first wire-bond pad 616, the process includes first attaching the second bond wire at a second die bond pad (not pictured), followed by second attaching the second bond wire at the second wire-bond pad.

FIG. 7 is a top plan of a package similar to the package depicted in FIG. 6 according to an embodiment. A die 724 is depicted mounted upon an upper protective layer 712 of a mounting substrate 700. A die bond pad 726 is coupled to a wire-bond pad 716 through a bond wire 728. In this embodiment, the plurality of wire-bond pads 716 is depicted as substantially the same size and pitch as the plurality of die bond pads 726. The wire-bond pads 716, however, are not depicted as directly over any given bump 734, which are depicted in phantom lines. Accordingly, a trace (not pictured) such as the trace 633 depicted in FIG. 6, couples the wire-bond pad 716 to a given bump 734. According to this embodiment, a uniform or substantially uniform ball-grid array (BGA) such as the bumps 734 can be achieved, while maintaining the embodiment of having each wire-bond pad directly over a via. In an embodiment, however, at least one wire-bond pad is disposed directly over its respective via, but not all wire-bond pads in the package are thus disposed.

In an embodiment, a process of wirebonding includes reverse wire bonding. The process includes first attaching the first bond wire 728 at the first wire-bond pad 716, followed by second attaching the first bond wire 728 at a first die bond pad 726. In an embodiment, a process of wirebonding includes forward wire bonding. The process includes first attaching the first bond wire 728 at the first die bond pad 726, followed by second attaching the first bond wire 728 at the first wire-bond pad 716.

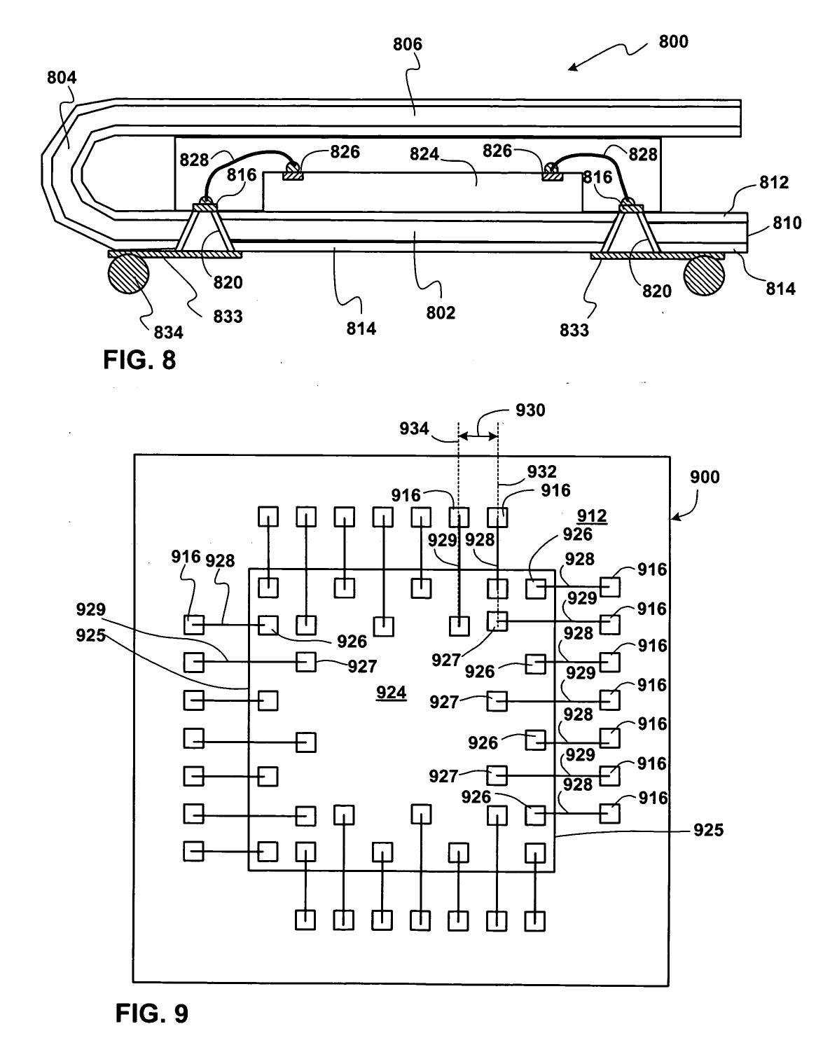

FIG. 8 is a side cross-section of a package according to an embodiment. In an embodiment, a mounting substrate 800 includes a substrate core 810, an upper protective layer 812, and a lower protective layer 814. The substrate 800 also includes a die-level section 802, a folded section 804, and an above-die section 806.

A first via 820 is depicted penetrating the substrate core 810, the upper protective layer 812, and the lower protective layer 814. A wire-bond pad 816 is depicted directly above the first via 820. In an embodiment, a second via (not pictured) such as the second via 419 in FIG. 5, provides electrical communication for a staggered wire-bond pad array such as is depicted in FIG. 4.

FIG. 8 also depicts a die 824 disposed upon the upper protective layer 812. Additionally, a bump 834 that is not directly below the first via 820 is disposed below the mounting substrate 800. The bump 834 is coupled to the first via 820 by a first trace 833. Consequently, the die 824 communicates to the bump 834 commencing with a die bond pad 826, the bond wire 828, the first wire-bond pad 816, and the trace 833.

In an embodiment, a process of wirebonding includes reverse wire bonding as set forth herein. Where a second bond wire is present for a staggered wire-bond pad with respect to the first wire-bond pad 816, the process includes first attaching the second bond wire at the second wire-bond pad, followed by second attaching the second bond wire at a second die bond pad. In an embodiment, a process of wirebonding includes forward wire bonding as set forth herein.

FIG. 9 is a top plan of a package according to an embodiment. In FIG. 9, a mounting substrate 900 includes a die 924 including a die edge 925. A first plurality of die bond pads 926 are proximate the die edge 925 at a first distance. A second plurality of die bond pads 927 are proximate the die edge 925 at a second distance. The first plurality of die bond pads 926 and the second plurality of die bond pads 927 are arrayed in a staggered configuration with respect to the die edge 925. In this embodiment, a plurality of wire-bond pads 916 is arrayed in a linear pattern with respect to the die edge 925. The package 900 illustrates the wire-bond pads 916 arrayed with a first pitch in relation to the staggered configuration of the first and second die bond pads 926 and 927, respectively. The staggered configuration includes substantially the same pitch as the wire-bond pads 916. The substantially same pitch is defined by the spacing 930 between a first symmetry line 932 and a second symmetry line 934.

Each first die bond pad 926 is coupled to a respective first wire-bond pad 916 by a first bond wire 928. Similarly, each second die bond pad 927 is coupled to a respective second wire-bond pad 917 by a second bond wire 929. In an embodiment, electronic tuning of the package is done by making the first bond wire 928 the same length, or the like, as the second bond wire 929.

In an embodiment, a process of wirebonding includes reverse wire bonding as set forth herein. Where a second bond wire is present for a second die bond pad 927 with respect to the first die bond pad 926, the process includes first attaching the second bond wire at the first wire-bond pad 926, followed by second attaching the second bond wire at a second die bond pad 927. In an embodiment, a process of wirebonding includes forward wire bonding as set forth herein.

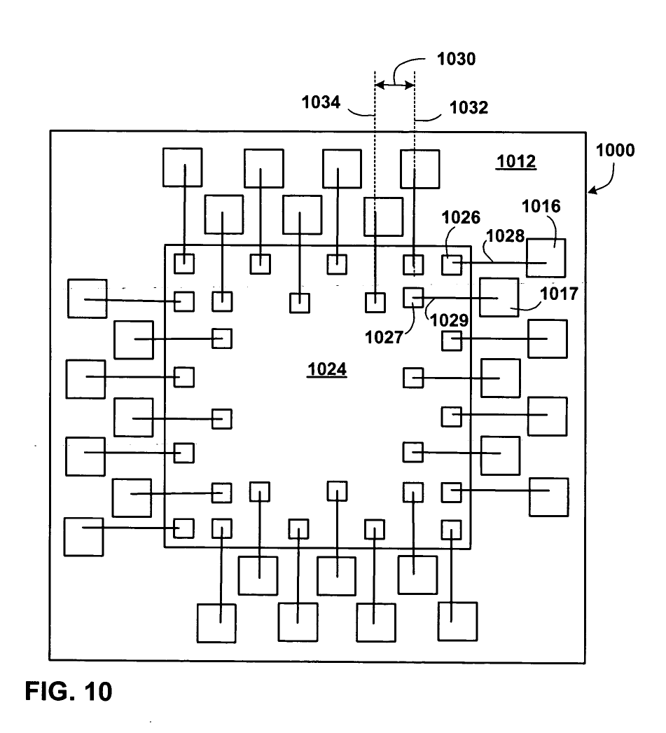

FIG. 10 is a top plan of a package according to an embodiment. A die 1024 is depicted mounted upon an upper protective layer 1012 of a mounting substrate 1000. In this embodiment, both the die bond pads 1026 and 1027, respectively, are staggered, as well as the wire-bond pads 1016 and 1017, respectively. In an embodiment, the bond wires 1028 and 1029 are all substantially the same electronically with regard to tuning the package.

The package 1000 illustrates first and second wire-bond pads 1016 and 1017, respectively, arrayed with a first pitch in relation to the staggered configuration of the first and second die bond pads 1026 and 1027, respectively, each with substantially the same pitch as the wire-bond. The substantially same pitch is defined by the spacing 1030 between a first symmetry line 1032 and a second symmetry line 1034.

In an embodiment, a process of wirebonding includes reverse wire bonding as set forth herein. In an embodiment, a process of wirebonding includes forward wire bonding as set forth herein.

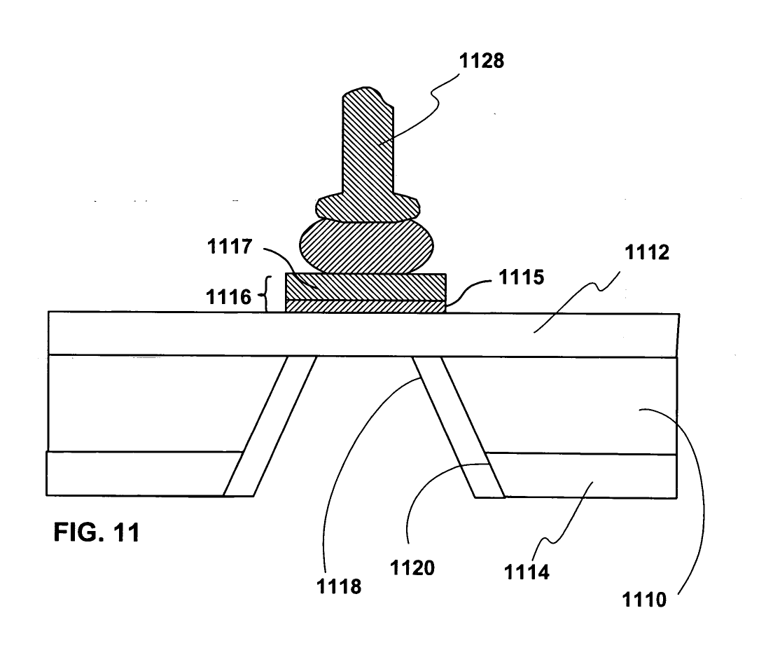

FIG. 11 is a side cross-section of a package according to an embodiment. A substrate core 1110 is laminated with an upper protective layer 1112, and a lower protective layer 1114. A wire-bond pad 1116 is depicted upon the upper protective layer 1112. The wire-bond pad 1116 includes a flash plating layer 1115 and a heavy plating layer 1117. In an embodiment, the heavy plating layer 1117 is a material that resists alloying with bond wire material.

A via 1118 is depicted penetrating the substrate core 1110, the upper protective layer 1112, and the lower protective layer 1114. The wire-bond pad 1116 is depicted as a raised structure above the upper protective layer 1112. In an embodiment, the wire-bond pad 1116 is at least flush with the upper protective layer 1112. In an embodiment, a via liner 1120 is a metallic or otherwise electrically conductive material that provides an electrical path through the substrate core 1110.

A bond wire 1128 is depicted as having been bonded to the wire-bond pad 1116. The metal of the bond wire 1128 is selected from aluminum or an aluminum alloy, gold or a gold alloy, silver or a silver alloy, doré, or platinum or a platinum alloy. One feature of an embodiment is the ability of the heavy plating layer 1117 to bond with bond wire 1128, but not to alloy therewith. In some applications, a bond wire article may be rejected by pulling or cutting the bond wires and repeating the bond wire process flow.

In an embodiment, the flash plating layer 1115 is a precious metal or precious metal alloy. In an embodiment, the flash plating layer 1115 is formed by a deposition process flow that is electroless plating. In an embodiment, the precious metal for the flash plating layer 1115 includes silver, gold, platinum, and combinations thereof. In an embodiment, the flash plating layer 1115 is primarily gold, such as a majority thereof or a plurality thereof. In an embodiment, the flash plating layer 1115 is primarily silver such as a majority thereof or a plurality thereof. In an embodiment, the precious metal for the flash plating layer 1115 includes nickel, palladium, platinum, and combinations thereof. In an embodiment, the flash plating layer 1115 is primarily platinum such as a majority thereof or a plurality thereof. In an embodiment, the precious metal for the flash plating layer 1115 includes cobalt, rhodium, iridium, and combinations thereof. In an embodiment, the flash plating layer 1115 is primarily iridium such as a majority thereof or a plurality thereof.

In an embodiment, the heavy plating layer 1117 is formed of identical material to the flash plating layer 1115. In an embodiment, the heavy plating layer 1117 is at least one of a more noble, or a softer (more ductile) metal than the flash plating layer 1115. In an embodiment, the heavy plating layer 1117 is selected from gold, doré, platinum, and other compositions that are more noble and more ductile than the flash plating layer 1115.

An embodiment includes a heavy plating layer 1117 that resists alloying with the bond wire 1128 during ordinary wire-bonding process flows. In an embodiment, an aluminum or aluminum alloy bond wire 1128 is attached to the heavy plating layer 1117. In an embodiment, a gold or gold alloy bond wire 1128 is attached to the heavy plating layer 1117. In an embodiment, a silver or silver alloy bond wire 1128 is attached to the heavy plating layer 1117. In an embodiment, a doré bond wire 1128 is attached to the heavy plating layer 1117. In an embodiment, a platinum or platinum alloy bond wire 1128 is attached to the heavy plating layer 1117.

In an embodiment, the formation of the heavy plating layer 1117 is carried out according to vapor deposition techniques, or by liquid plating techniques as set forth herein. In an embodiment, formation of the heavy plating layer 1117 is carried out by electroless plating by using a gold-cyanide electroless plating solution, and the Merrill-Crowe or other precipitation technique. In this embodiment, an atom-thick layer of zinc (Zn, not pictured) is pre-plated onto the flash plating layer 1115 by an electroless process that does not substantially cover the upper protective layer 1112, and the gold-cyanide solution is contacted with the zinc which causes the reduction of the gold out of the gold-cyanide complex.

In an electroless plating embodiment, a gold halide solution is Eh-pH manipulated according to the technique pioneered by Pourbaix. In an embodiment, the flash plating layer 1115 acts as an autocatalytic surface to assist the selective precipitation of the heavy plating layer 1117.

In an embodiment, the heavy plating layer 1117 is formed by a chemical vapor deposition (CVD) process that is carried out during which an organometallic gold vapor or a gold halide vapor is metered, blanket deposited, and patterned with an etch. In an embodiment, the heavy plating layer 1117 is formed by a physical vapor deposition (PVD) process that is carried out in which a gold target is impinged under PVD conditions to form a blanket layer of gold that is subsequently patterned into the heavy plating layer 1117.

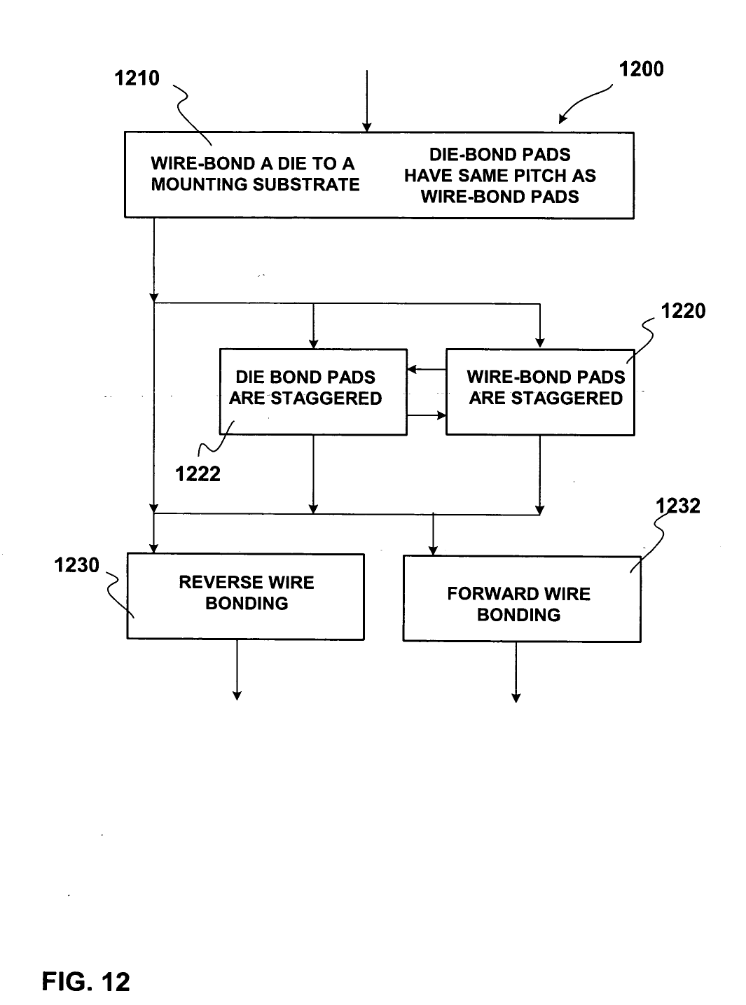

FIG. 12 is a process flow diagram according to various embodiments. The process 1200 includes wire-bonding a wire-bond pad and a die bond pad, where the wire-bond pad is in a first array and the die bond pad is in a second array, and where the first array and the second array include substantially the same pitch. In an embodiment, the pitch is in a range from about 50 μm to about 200 μm. In an embodiment, the pitch is about 75 μm. In an embodiment, the pitch is about 135 μm. In an embodiment, the pitch is about 150 μm.

At 1210, the process can commence by forming the wire-bond pad on a mounting substrate. In an embodiment, the process flow terminates at 1210.

At 1220, the wire-bond pads are staggered. According to a process flow embodiment, the wire-bond pads are staggered and the die bond pads are substantially linear as set forth herein. In an embodiment, the process flow terminates at 1220.

At 1222, the die bond pads are staggered. According to a process flow embodiment, the die bond pads are staggered and the wire-bond pads are substantially linear as set forth herein. In an embodiment, the process flow terminates at 1222.

According to a process flow embodiment, the die bond pads are staggered and the die bond pads are staggered as set forth herein. In an embodiment, the process flow terminates after passing through 1220 and 1222.

At 1230, the process flow includes an embodiment of reverse wire bonding as set forth herein. In an embodiment, the process flow terminates at 1230.

At 1232, the process flow includes an embodiment of forward wire bonding as set forth herein. In an embodiment, the process flow terminates at 1232.

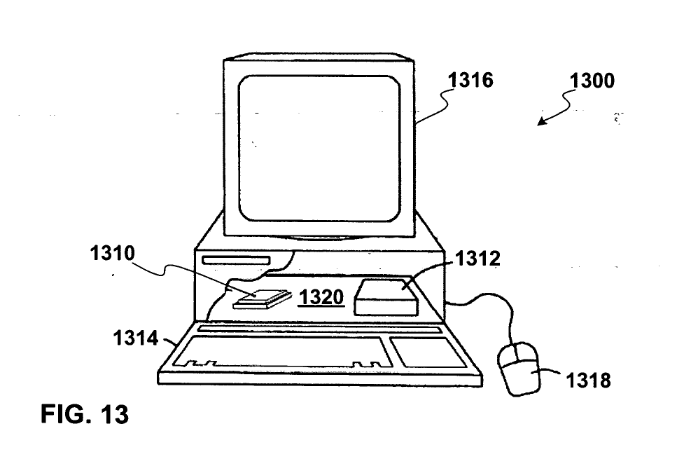

FIG. 13 is a depiction of a computing system according to an embodiment. One or more of the foregoing embodiments of a substantially same-pitch wire-bond pad to die bond pad configuration may be utilized in a computing system, such as a computing system 1300 of FIG. 13. The computing system 1300 includes at least one processor (not pictured) which is enclosed in a microelectronic device package 1310, a data storage system 1312, at least one input device such as keyboard 1314, and at least one output device such as monitor 1316, for example. The computing system 1300 includes a processor that processes data signals, and may include, for example, a microprocessor, available from Intel Corporation. In addition to the keyboard 1314, the computing system 1300 can include another user input device such as a mouse 1318, for example. Similarly, depending upon the complexity and type of system, the computing system 1300 can include a board 1320 for mounting at least one of the microelectronic device package 1310, the data storage system 1312, or other components.

For purposes of this disclosure, a computing system 1300 embodying components in accordance with the claimed subject matter may include any system that utilizes a microelectronic device package, which may include, for example, a data storage device such as dynamic random access memory, polymer memory, flash memory, and phase-change memory. The microelectronic device package can also include a die that contains a digital signal processor (DSP), a micro controller, an application specific integrated circuit (ASIC), or a microprocessor.

Embodiments set forth in this disclosure can be applied to devices and apparatuses other than a traditional computer. For example, a die can be packaged with an embodiment of the substantially same-pitch wire-bond pad to die bond pad configuration, and placed in a portable device such as a wireless communicator or a hand-held device such as a personal data assistant and the like. Another example is a die that can be packaged with an embodiment of the substantially same-pitch wire-bond pad to die bond pad configuration and placed in a vehicle such as an automobile, a locomotive, a watercraft, an aircraft, or a spacecraft.

The Abstract is provided to comply with 37 C.F.R. §1.72(b) requiring an Abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

What is claimed is:

1. An article comprising:
a die disposed upon a mounting substrate;
a die bond-pad array disposed upon the die, wherein the die bond-pad array includes a first pitch; and
a substrate bond-pad array disposed upon the mounting substrate, wherein the substrate bond-pad array includes a second pitch, and wherein the first pitch is substantially equivalent to the second pitch.

2. The article of claim 1, wherein the second pitch is staggered, and wherein the second pitch is quantified by a first substrate bond pad disposed along a first symmetry line and a second substrate bond pad that is staggered in relation to the first bond pad, and that is disposed along a second symmetry line, and wherein the first symmetry line and the second symmetry line are spaced apart by a distance substantially equivalent to the first pitch.

3. The article of claim 1, wherein the first pitch includes an amount in a range from about 50 micrometer (μm) and about 200 μm.

4. The article of claim 1, wherein the first pitch includes an amount of about 135 μm.

5. The article of claim 1, wherein the mounting substrate is selected from a rigid substrate, a flex substrate, and a folded flex substrate.

6. The article of claim 1, wherein the die bond-pad array includes a staggered configuration with respect to the die at a first edge.

7. The article of claim 1, wherein the substrate bond-pad array includes a staggered configuration with respect to the substrate.

8. The article of claim 1, wherein the die bond-pad array includes a die-staggered configuration with respect to the die at a first edge, and wherein the substrate bond-pad array includes a staggered configuration with respect to the substrate.

9. The article of claim 1, wherein the wire-bond pad includes a first layer and a second layer, and wherein the second layer is one of identical material to the first layer, or at least one of a more noble, or a softer metal than the first layer.

10. The article of claim 1, wherein the substrate is selected from a rigid substrate, a flex substrate, and a folded-flex substrate.

11. An article comprising:
a die disposed upon a wire-bonding mounting substrate, wherein the wire-bonding mounting substrate includes a first surface and a second surface;
a die bond-pad array disposed upon the die, wherein the die bond-pad array includes a first pitch;
a substrate bond-pad array disposed upon the wire-bonding mounting substrate, wherein the substrate bond-pad array includes a second pitch, and wherein the first pitch is substantially equivalent to the second pitch;
in the substrate bond-pad array, a first wire-bond pad disposed upon the first surface; and
a first via in the wire-bonding mounting substrate, wherein the first via is in electrical contact with the first wire-bond pad, and wherein the first via is disposed directly below the first wire-bond pad.

12. The article of claim 11, wherein the first pitch includes an amount in a range from about 50 micrometer (μm) and about 200 μm.

13. The article of claim 11, wherein the first pitch includes an amount of about 135 μm.

14. The article of claim 11, wherein the mounting substrate is selected from a rigid substrate, a flex substrate, and a folded flex substrate.

15. The article of claim 11, wherein the die bond-pad array includes a staggered configuration with respect to the die at a first edge.

16. The article of claim 11, wherein the substrate bond-pad array includes a staggered configuration with respect to the substrate.

17. The article of claim 11, wherein the die bond-pad array includes a staggered configuration with respect to the die at a first edge, and wherein the substrate bond-pad array includes a staggered configuration with respect to the substrate.

18. The article of claim 11, wherein the wire-bond pad includes a first layer and a second layer, and wherein the second layer is one of identical material to the first layer, or at least one of a more noble, or a softer metal than the first layer.

19. A computing system comprising:
a die disposed upon a mounting substrate;
a die bond-pad array disposed upon the die, wherein the die bond-pad array includes a first pitch;
a substrate bond-pad array disposed upon the mounting substrate, wherein the substrate bond-pad array includes a second pitch, and wherein the first pitch is substantially equivalent to the second pitch; and
at least one of an input device and an output device coupled to a substrate bond-pad in the substrate bond-pad array.

20. The computing system of claim 19, wherein the computing system is disposed in one of a computer, a wireless communicator, a hand-held device, an automobile, a locomotive, an aircraft, a watercraft, and a spacecraft.

21. The computing system of claim 19, wherein the die is selected from a data storage device, a digital signal processor, a micro controller, an application specific integrated circuit, and a microprocessor.

22. The computing system of claim 19, wherein the die is disposed in a computer shell.

23. The computing system of claim 19, wherein the mounting substrate is selected from a rigid substrate, a flex substrate, and a folded flex substrate.

24. A process comprising:
wire-bonding a die to a mounting substrate, wherein the die includes a die bond-pad array disposed upon the die, wherein the die bond-pad array includes a first pitch, wherein the mounting substrate includes a substrate bond-pad array disposed upon the mounting substrate, wherein the substrate bond-pad array includes a second pitch, and wherein the first pitch is substantially equivalent to the second pitch.

25. The process of claim 24, wherein wire-bonding is selected from forward wire-bonding and reverse wire-bonding.

26. The process of claim 24, wherein wire-bonding includes wire-bonding at the first pitch in a range from about 50 micrometer (μm) and about 200 μm.

27. The process of claim 24, wherein wire-bonding includes wire-bonding from a die bond-pad array in a die bond-pad staggered configuration.

28. The process of claim 24, wherein wire-bonding includes wire-bonding from a substrate bond-pad array in a substrate bond-pad staggered configuration.

29. The process of claim 24, wherein wire-bonding includes wire-bonding from a die bond-pad array in a die bond-pad staggered configuration, and includes wire-bonding from a substrate bond-pad array in a substrate bond-pad staggered configuration.

30. The process of claim 24, wherein wire-bonding includes wire-bonding to a substrate selected from a rigid substrate, a flex substrate, and a folded flex substrate.
